(19) United States
(12) Patent Application Publication
(10) Pub. No.: US 2026/0093774 A1
(43) Pub. Date: Apr. 2, 2026

(54) APPROXIMATE COMPUTING DIGITAL CIRCUIT FOR POST-QUANTUM CRYPTOGRAPHY APPLICATIONS

(71) Applicant: COMMISSARIAT A L'ENERGIE ATOMIQUE ET AUX ENERGIES ALTERNATIVES, Paris (FR)

(72) Inventors: Emanuele VALEA, Grenoble Cedex 09 (FR); Romain WACQUEZ, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/887,086

(22) Filed: Sep. 17, 2024

(30) Foreign Application Priority Data
Sep. 28, 2023 (FR) 2310361

(51) Int. Cl. G06F 17/16; H03K 19/20

(52) U.S. Cl. CPC G06F 17/16; H03K 19/20

(57) ABSTRACT

A digital circuit for including a scalar product between two vectors (a₀, a₁, . . . , aᵢ, . . . , a_{N-1}) and (s₀, s₁, . . . , sᵢ, . . . , s_{N-1}). The digital circuit includes a multiplier, an accumulator including at least one adder and a register, as well as a control circuit of the accumulator. At a clock tick of index i, the multiplier is configured to compute the result rᵢ of the multiplication aᵢ×sᵢ, and the accumulator is configured to add rᵢ with the current value of the register. Afterwards, the result of the addition is memorised in the register. The control circuit is configured to control the accumulator so as to perform the addition in an approximate manner for at least one addition amongst the N additions of the computation of the scalar product. In particular, the digital circuit is intended to be used in an electronic device implementing a cryptographic algorithm based on a “Learning With Errors” (LWE) technology.

### TECHNICAL FIELD

The present invention belongs to the field of approximate computing digital circuits for cryptography applications, and more particularly for post-quantum cryptography applications.

### BACKGROUND

Post-quantum cryptography covers encryption algorithms that could resist mathematical attacks using a quantum computer.

Unlike a conventional computer which works on binary data, a quantum computer works on qubits whose quantum state can have a quantum value including several simultaneous possibilities. Quantum computation is particularly suited to problems whose computing complexity pertains to combinatorics. These problems are found in particular in cryptography. Thus, the large factorisation capacities of a quantum computer would allow mathematically breaking numerous conventional cryptographic systems, in particular asymmetric encryption methods based on the RSA algorithm.

“Learning with errors”, or LWE (acronym standing for “Learning With Errors”) is a computing problem deemed to be difficult which is at the basis of many recent encryption algorithms used in post-quantum cryptography.

A conventional implementation of an LWE-based cryptographic primitive consists in generating errors which follow a predetermined error distribution, and in adding these errors in exact computations. However, the generation of errors with a hardware random (or pseudo-random) number generator (TRNG, for “True Random Number Generator”, or PRNG, for “Pseudo-Random Number Generator”) results in performance problems.

The document “When Bad News Become Good News—Towards Usable Instances of Learning With Physical Errors”, D. BELLIZIA et al., IACR Transactions on Cryptographic Hardware and Embedded Systems, pp. 1-24, August 2022, discloses a digital circuit for computing a scalar product of two vectors. This circuit may serve as a basic brick to implement an LWE-type algorithm. In the proposed architecture, each vector includes 128 numbers each encoded over 8 bits. The digital circuit includes a parallel multiplier capable of computing 128 multiplications in parallel, as well as seven levels of parallel adders. Each of the adders of the different levels performs, in parallel, a number of additions respectively equal to 64, 32, 16, 8, 4, 2 and then 1. Shift registers (flip-flop latches) are interposed between two levels of adders to introduce an error in sampling of the least significant bit of the result of two of the additions. The proposed architecture is particularly complex and it has a quite large size.

In another field, for intensive computing digital circuits used in applications having a certain resilience to errors (for example for the implementation of neural networks for image processing), it is known to introduce simplifications in the digital circuit in order to optimise its energy consumption and/or its size to the detriment of the accuracy of the computation. We then talk about “approximate computing”. The digital circuit is then specifically synthesised so as to make computations with a determined error probability. Thus, there is generally no means for dynamically controlling the probability of error introduced in the computations by the digital circuit.

### SUMMARY

An objective of the present invention is to overcome all or part of the drawbacks of the prior art, in particular those set out hereinbefore.

To this end, and according to a first aspect, the present invention provides a digital circuit for computing a scalar product between two N-dimension vectors, N being an integer at least equal to two. The two vectors are respectively denoted (a₀, a₁, . . . , aⱼ, . . . , a_{N-1}) and (s₀, s₁, . . . , sⱼ, . . . , s_{N-1}). The digital circuit includes a multiplier, an accumulator including at least one adder and a register, as well as a control circuit of the accumulator. The digital circuit is configured to be clocked by a clock, and at a clock tick of index j, j being an integer varying between 0 and (N−1):
the multiplier is configured to compute a result rⱼ of a multiplication aⱼ×sⱼ of the components of index j of the two vectors,
the accumulator is configured to add the result rⱼ of the multiplication with a current value of the register, and to memorise a result of the addition in the register;
the control circuit is configured to control the accumulator so as to perform the addition in an approximate manner, i.e. with a predetermined level of probability that the result of the addition includes an error, for at least one addition amongst the N additions of the computation of the scalar product.

This digital circuit is particularly well suited to serve as a hardware accelerator for a cryptographic primitives based on a “learning with errors” (LWE) algorithm. Indeed, the scalar product computation is at the basis of this type of algorithms.

The control circuit allows injecting an error for one or more addition(s) of the computation of the scalar product. This allows implementing an LWE-type algorithm without having to use any hardware random (or pseudo-random) number generator (TRNG or PRNG), while keeping a particularly simple and compact architecture. In particular, and unlike the solution disclosed in the prior art, there is no need to arrange in cascade several levels of adders and there is no need to add any bank of registers.

The proposed solution has a compact architecture, with a reduced size (small surface area occupied by the circuit) and a relatively low energy consumption.

The proposed architecture confers flexibility on the error probability level desired for the computation of the scalar product. For example, it is possible to dynamically modify, via the control circuit, the number of additions that have to be executed in an approximate manner in order to modify the error distribution. The proposed architecture also allows adding entropy into the obtained error distribution, in particular by acting on the selection of the addition(s) that have to be executed in an approximate manner in the computation of the scaler product.

In particular embodiments, the invention may further include one or more of the following features, considered separately or according to any technically-feasible combinations.

In particular embodiments:
the accumulator includes one single adder implemented according to the “Fully-Depleted Silicon-On-Insulator”, FDSOI, technology;
a predetermined region of the adder groups together FDSOI transistors forming logic gates which control a predetermined number L of least significant bits of the result of the addition, L being an integer at least equal to one;
said predetermined region is connected to a voltage source for applying a back-gate voltage to the FDSOI transistors of the region, the value of the back-gate voltage being dynamically controllable by the control circuit,
the control circuit is configured to apply by default a back-gate voltage reference value, and to apply a back-gate voltage specific value, different from the reference value, only during the execution of said at least one addition to be performed in an approximate manner.

Such arrangements correspond to a particularly compact architecture (a digital circuit with one single adder) with an increased level of flexibility on the error distribution that can be obtained. Indeed, it is possible to dynamically modify the error distribution according to the value of the applied back-gate voltage. The back-gate voltage allows varying the threshold voltage of the FDSOI transistors. A higher threshold voltage results in an increase in the propagation time of the logic gates implemented by the transistors, and consequently a loss of accuracy in the computations. The predetermination of the considered region (which depends on the number of least significant bits that one wishes to be affected by the approximate computation) also contributes to the definition of the error distribution.

In particular embodiments, the control circuit is configured to dynamically determine the back-gate voltage specific value to be applied according to an error probability level desired for the computation of the scalar product.

In particular embodiments, the FDSOI transistors are arranged into CMOS structures each including an NMOS transistor on a P well and a PMOS transistor on an N well.

This corresponds to a digital circuit with CMOS components with a conventional structure (“Regular Well”) optimised for a back-gate reverse polarisation (“Reverse Body Bias” or RBB). In such a configuration, the back-gate reverse polarisation (RBB) is applied to increase the threshold voltage of the transistor. The transistor is then of the RVT type (“Regular Voltage Threshold”).

In particular embodiments:
the accumulator includes an exact adder synthesised specifically to compute an addition in an exact manner, an approximate adder synthesised specifically to compute an addition with the predetermined error probability level, and a multiplexer;
for each addition executed at a clock tick of index j, the multiplexer is configured by the control circuit to select the adder to be used amongst the exact adder and the approximate adder.

This architecture does not require any dynamic voltage source, but it requires two adders and one multiplexer.

In particular embodiments, said at least one addition to be executed in an approximate manner, amongst the N additions of the computation of the scalar product, is different at each new scalar product computation.

In particular embodiments, said at least one addition to be executed in an approximate manner in the computation of the scalar product is randomly selected.

In particular embodiments, the number of additions to be executed in an approximate manner in the computation of the scalar product is dynamically controlled by the control circuit according to an error probability level desired for the computation of the scalar product.

According to a second aspect, the present invention provides an electronic device implementing a cryptographic algorithm based on a “Learning With Errors” (LWE) technology. The device includes at least one digital circuit according to any one of the preceding embodiments.

### BRIEF DESCRIPTION OF THE DRAWINGS

The invention will be better understood upon reading the following description, given as a non-limiting example, and made with reference to FIGS. 1 to 7 which show:

FIG. 1 a generic schematic illustration of a digital circuit according to the invention, for the computation of a scalar product between two vectors,

FIG. 2 a schematic illustration of a first particular embodiment of the digital circuit illustrated in FIG. 1,

FIG. 3 a schematic illustration of a second particular embodiment of the digital circuit illustrated in FIG. 1,

FIG. 4 a schematic illustration of an FDSOI transistor,

FIG. 5 a schematic illustration of an FDSOI CMOS structure optimised for the RBB mode,

FIG. 6 a schematic illustration of an 8-bit adder, with the identification of a particular region of the adder which affects the least significant bit of the result of the addition,

FIG. 7 a graph illustrating the possibility of controlling the error probability level of the adder as a function of the applied back-gate voltage.

In these figures, identical references from one figure to another designate identical or similar elements. For clarity, the illustrated elements are not necessarily plotted to the same scale, unless stated otherwise.

### DETAILED DESCRIPTION OF EMBODIMENTS

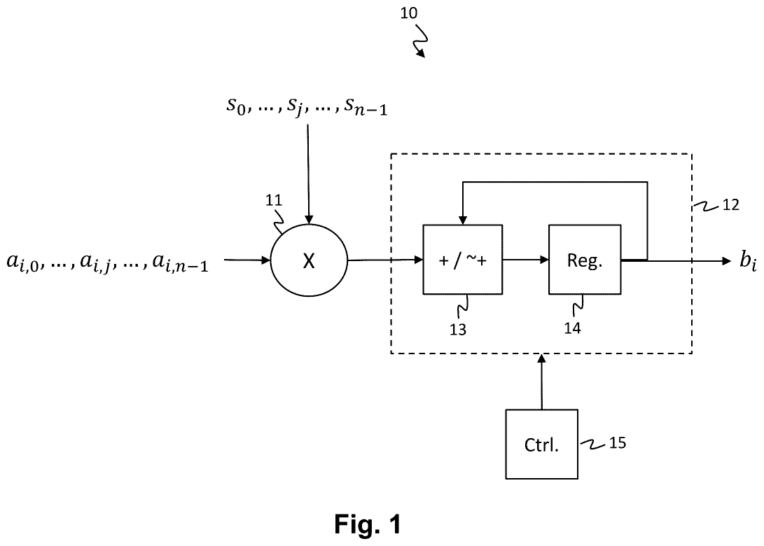

FIG. 1 schematically shows a digital circuit 10 according to the invention. The digital circuit 10 is configured to compute a scalar product between two N-dimension vectors, N being an integer at least equal to two. In the example illustrated in FIG. 1, the two vectors are respectively denoted (a_{i,0}, a_{i,1}, . . . , a_{i,j}, . . . , a_{i,N-1}) and (s₀, s₁, . . . , sⱼ, . . . , s_{N-1}). The components a_{i,j} and sⱼ of these two vectors, j being an integer varying between 0 and (N−1), each corresponding for example to an integer encoded over N_{B} bits, N_{B} being an integer at least equal to one.

The digital circuit 10 is configured to compute the scalar product bᵢ of the two vectors:

$${b}_{i} = {\sum }_{j = 0}^{N - 1} {a}_{i , j} \cdot {s}_{j} \qquad [ Math . 1 ]$$

Repeating this operation for N different vectors (a_{i,0}, a_{i,1}, . . . , a_{i,j}, . . . , a_{i,N-1}), by varying the index i between 0 and (N−1), then amounts to computing the following matrix product:

$$( \begin{matrix}{a}_{0 , 0} & ⋯ & {a}_{0 , N - 1} \\ ⋮ & ⋱ & ⋮ \\ {a}_{N - 1 , 0} & ⋯ & {a}_{N - 1 , N - 1}\end{matrix} ) ( \begin{matrix}{s}_{0} \\ ⋮ \\ {s}_{N - 1}\end{matrix} ) = ( \begin{matrix}{b}_{0} \\ ⋮ \\ {b}_{N - 1}\end{matrix} ) \qquad [ Math . 2 ]$$

As it will be seen later on, instead of computing this operation in an exact manner, the digital circuit 10 is configured to compute this operation in an approximate manner, i.e. such that the obtained result is vitiated by an error having a predetermined distribution:

$$( \begin{matrix}{a}_{0 , 0} & ⋯ & {a}_{0 , N - 1} \\ ⋮ & ⋱ & ⋮ \\ {a}_{N - 1 , 0} & ⋯ & {a}_{N - 1 , N - 1}\end{matrix} ) ( \begin{matrix}{s}_{0} \\ ⋮ \\ {s}_{N - 1}\end{matrix} ) + ( \begin{matrix}{e}_{0} \\ ⋮ \\ {e}_{N - 1}\end{matrix} ) = ( \begin{matrix}{b}_{0} \\ ⋮ \\ {b}_{N - 1}\end{matrix} ) \qquad [ Math . 3 ]$$

Each element eⱼ corresponds to an error according to a predetermined error distribution.

Such a computation is at the basis of cryptographic primitives based on learning with errors (LWE). Hence, the digital circuit 10 is particularly well suited to be used as a hardware accelerator to implement this type of cryptographic primitives.

As illustrated in FIG. 1, the digital circuit 10 includes a multiplier 11, an accumulator 12 and a control circuit 15 of the accumulator 12. The accumulator 12 includes at least one adder 13 and one register 14. The digital circuit 10 is configured to be clocked by a clock.

Next, focus will be placed on the computation of the scalar product described in the formula [Math. 1], for a given index i. The register 14 is initialised to zero at the beginning of the computation of the scalar product. At a clock tick of index j, the multiplier 11 is configured to compute a result r of a multiplication a_{i,j}×sⱼ of the components of index j of the two vectors, and the accumulator 12 is configured to add the result rⱼ of the multiplication with a current value of the register 14. The result of the addition is then memorised in the register 14. The result of the computation of the scalar product described in the formula [Math. 1] then corresponds to the value bᵢ taken by the register 14 after N clock ticks corresponding to the variation of the index j from 0 to (N−1). In turn, the result of the matrix computation described by the formula [Math.2] may be obtained within N² clock ticks.

The particularity of the digital circuit 10 according to the invention is that the control circuit 15 allows dynamically controlling the accumulator 12 to perform the addition operation either in an exact manner (which is illustrated by the symbol “+” in the figures) or in an approximate manner (which is illustrated by the symbol “˜+” in the figures). Performing the addition in an approximate manner amounts to performing the addition with a predetermined level of probability that the result of the addition includes an error.

More particularly, the control circuit 15 is configured to control the accumulator 12 so as to perform the addition in an approximate manner for at least one addition amongst the N additions of the computation of the scalar product (i.e. for at least one clock tick amongst the N clock ticks enabling the computation of the scalar product).

The clock tick of index j triggers the aforementioned two operations (the computation of the result rᵢ of the multiplication a_{i,j}×sⱼ, and the addition of the result rᵢ of the multiplication with the current value of the register 14). Nonetheless, it should be noted that it is not essential that the N clock ticks of index j enabling the computation of the scalar product are consecutive. In other words, these two operations are not necessarily performed during one single clock tick. For example, nothing would prevent from performing the multiplication and the addition on two successive clock ticks j and j′ (instead of performing them at one single clock tick j). Proceeding this way is but a variant of the invention.

FIG. 1 generically shows a digital circuit 10 according to the invention. The digital circuit 10 may be made according to different particular embodiments.

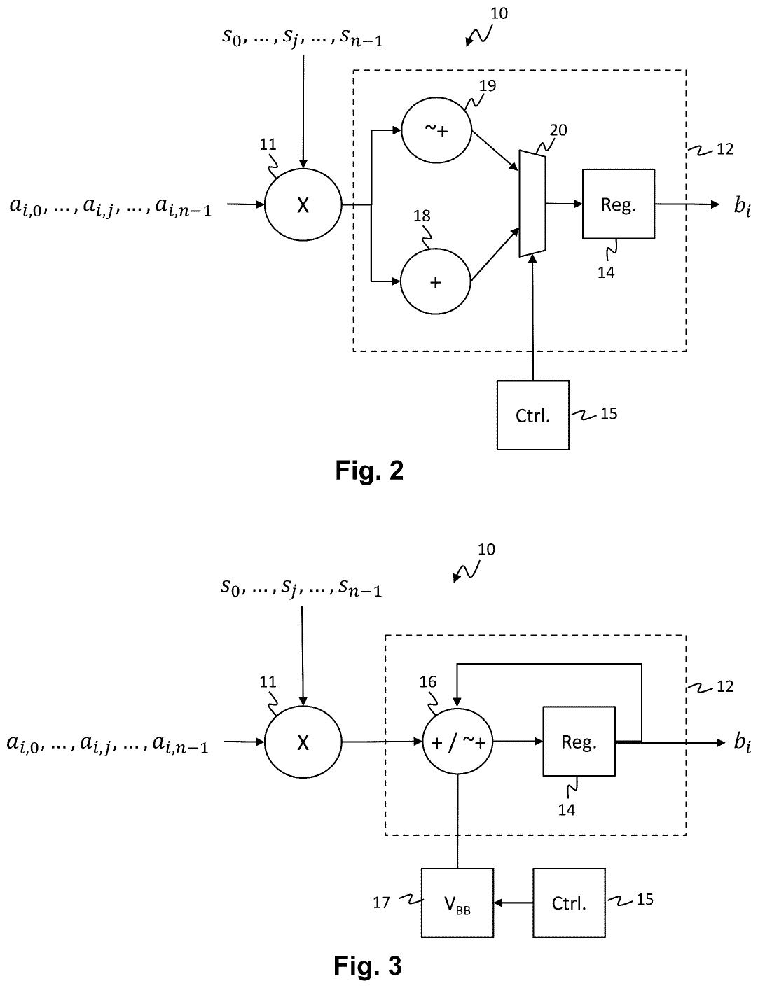

FIG. 2 schematically shows a first particular embodiment of the digital circuit 10 illustrated in FIG. 1. In this first embodiment, the accumulator 12 includes both an exact adder 18 and an approximate adder 19. The exact adder 18 is configured specifically to compute an addition in an exact manner. In turn, the approximate adder 19 is configured specifically to compute an addition with a predetermined error probability level.

The exact adder 18 corresponds to a conventional adder. During the design of the digital circuit 10, the exact adder 18 is synthesised specifically to compute an addition in an exact manner. In other words, the netlist of the exact adder 18 is optimised so as to ensure that the result of the addition performed by the exact adder 18 has a zero or negligible error probability under normal conditions of use of the digital circuit 10.

In turn, during the design of the digital circuit 10, the approximate adder 19 is synthesised specifically to compute an addition with a predetermined error probability level. In other words, the netlist of the approximate adder 19 is modified so as to ensure that the result of an addition performed by the approximate adder 19 has the desired error probability level. Thus, the adder 19 is approximated according to a “static” approach (when designing the digital circuit 10).

Different microarchitectures may be considered to design the approximate adder 19. For example, the library “EvoApproxLib LITE” proposes a large number of circuits of approximate adders associated with different error probability levels.

The accumulator 12 further includes a multiplexer 20. For each addition executed at a clock tick of index j, the multiplexer 20 is configured by the control circuit 15 to select the adder to be used amongst the exact adder 18 and the approximate adder 19. With such arrangements, the control circuit 15 is configured to control the accumulator 12 so as to perform the addition in an approximate manner for at least one addition amongst the N additions of the computation of the scalar product (i.e. for at least one clock tick amongst the N clock ticks enabling the calculation of the scalar product).

Advantageously, it is possible to dynamically control, via the control circuit 15, the number of additions that have to be executed in an approximate manner in the computation of the scalar product. In other words, it is possible to dynamically control the number of clock ticks (among the N clock ticks allowing computing the scalar product) corresponding to additions that have to be executed in an approximate manner.

Such arrangements confer some flexibility on the error probability level desired for the computation of the scalar product. Indeed, the larger the number of additions executed in an approximate manner, and the higher the error probability level for the computation of the scalar product will be. For example, it is possible to empirically determine different error probability levels for the computation of the scalar product according to different values of the number of additions executed in an approximate manner during the computation of the scalar product. Afterwards, it is then possible to configure the control circuit 15 to determine the number of additions that have to be executed in an approximate manner according to an error probability level desired for the computation of the scalar product.

It is also possible to consider dynamically controlling, via the control circuit 15, which additions have to be performed in an approximate manner in the computation of the scalar product.

In other words, it is possible to determine a number K comprised between 1 and (N−1) and different integers p₀, . . . , pₖ, . . . , p_{K} with 0≤pₖ≤(N−1) for any index k comprised between 0 and K, such that the multiplexer 20 is configured by the control circuit 15 to select the approximate adder 19 on the clock ticks of index pₖ, and to select the exact adder 18 on the other clock ticks.

Such arrangements allow adding entropy into the obtained error distribution. In particular, it is possible to consider changing the addition(s) executed in an approximate manner at each new scalar product computation (in other words, it is possible to consider varying all integers p₀, . . . , pₖ, . . . , p_{K} at each new scalar product computation). This entropy addition is particularly interesting in cryptography applications.

It is also possible to consider configuring the control circuit 15 to randomly select the additions that have to be performed in an approximate manner in the computation of the scalar product.

FIG. 3 schematically shows a second particular embodiment of the digital circuit 10 illustrated in FIG. 1. In this second embodiment, the accumulator 12 includes one single adder 16 implemented according to the Fully-Depleted Silicon-On-Insulator (FDSOI) technology for manufacturing electronic components.

The FDSOI technology is known for overcoming some limitations of the “CMOS on bulk substrate” technology (or “CMOS bulk”, CMOS is the acronym for “Complementary Metal-Oxide Semiconductor”). In particular, the FDSOI technology allows for better performances (in particular in terms of transition time and reliability) and a reduced energy consumption in comparison with the “CMOS bulk” technology (in particular, the FDSOI transistors can operate at lower voltages).

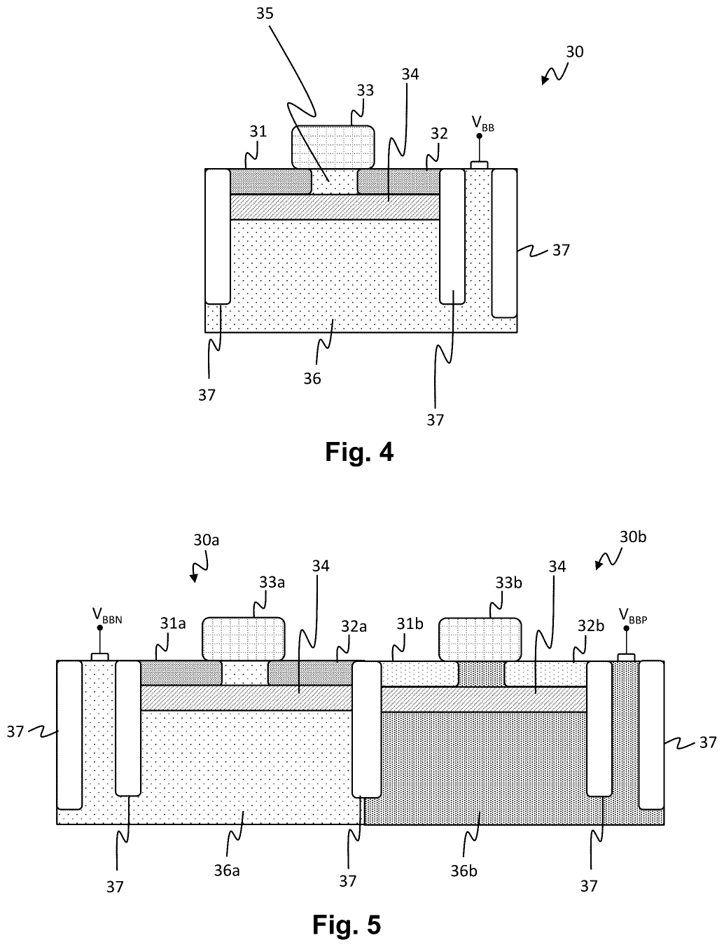

FIG. 4 schematically shows a FDSOI transistor 30. As illustrated in FIG. 4, the FDSOI transistor includes a substrate 36 made of silicon over which an ultra-thin insulating silicon oxide layer 34 is placed. The FDSOI transistor 30 also includes, over the insulating silicon oxide layer 34, a source 31, a drain 32 and a gate 33. A thin silicon layer located over the insulating silicon oxide layer forms an homogeneous channel 35 beneath the gate 33. Since the layer of the channel 35 is very thin, no doping of the channel is necessary (this is the reason why we talk about “fully-depleted” transistor). As illustrated in FIG. 4, the FDSOI transistor 30 may also include insulating trenches 37.

One feature of the FDSOI transistor 30 is that its performances can be modified by applying a voltage V_{BB} at the level of the substrate 36 forming its back face. We then talk about “back-face polarisation” or “back-gate polarisation”. The voltage V_{BB} is so-called “back-gate voltage” or “body bias voltage”. This polarisation of the substrate 36 allows varying the threshold voltage of the transistor 30. The variation of the threshold voltage of the transistor results in a change in the performances of the transistor in terms of rapidity, reliability and energy consumption.

As it will be seen in more detail later on, one could distinguish between “Regular Well” type transistors and “Flip Well” type transistors. A “Regular Well” type transistor is based on a CMOS structure with a P well beneath the NMOS and an N well beneath the PMOS, and it is optimised for the RBB (“Reverse Body Bias”) mode which allows favouring high threshold voltages (RVT-type transistor). A “Flip Well” type transistor is based on a CMOS structure with an N well beneath the NMOS and a P well beneath the PMOS), and it is optimised for the FBB (“Forward Body Bias”) mode which allows favouring low threshold voltages (LVT-type transistor, standing for “Low Voltage Threshold”). The threshold voltage of the RVT transistors is higher than that of the LVT transistors.

The polarisation of the substrate 36 creates a “rear gate” buried beneath the channel 35. The transistor then acts as a dual-gate transistor. This feature allows applying different voltages at the upper gate 33 and at the back gate. This polarisation of the substrate 36 is so-called “body bias”. By applying this polarisation according to known rules of a person skilled in the art (compliance with the polarisation conditions between the N well and the P well), the threshold voltage of an RVT transistor is increased (RBB mode), and the threshold voltage of an LVT transistor is reduced (FBB mode).

The insulating silicon oxide layer 34 limits current leakages in the substrate 36, this is the reason why it is possible to apply to the substrate 36 of the FDSOI transistor 30 a relatively high back-gate voltage (this is not the case with the “bulk” technology).

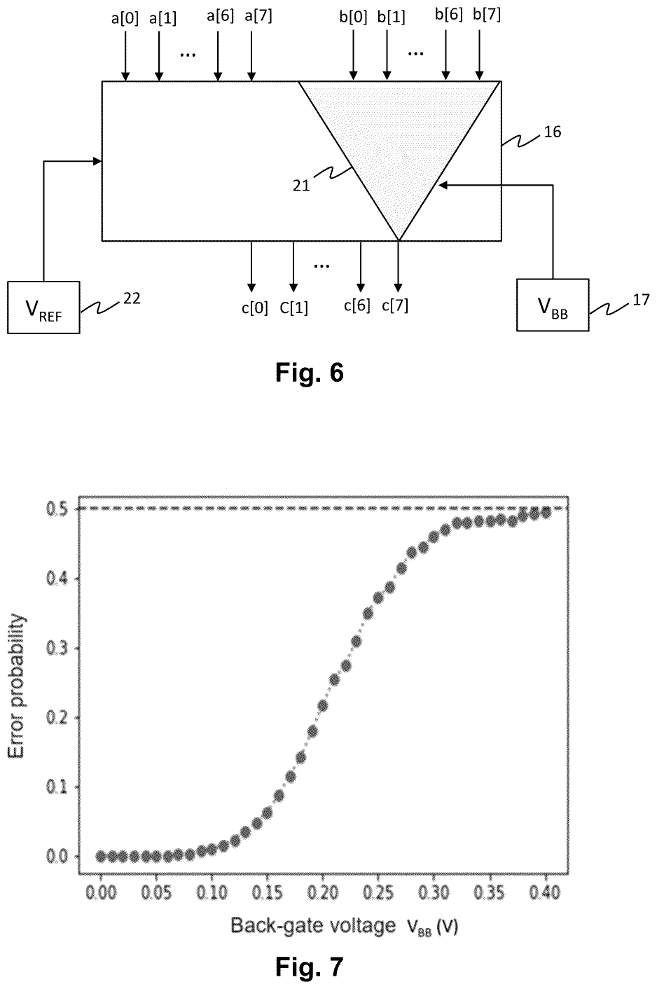

During the design of the digital circuit 10, and as illustrated in FIG. 6, a particular region 21 of the adder is predetermined. This predetermined region 21 groups together FDSOI transistors 30 forming logic gates which control a predetermined number L of least significant bits of the result of the addition, L being an integer at least equal to one. In the example illustrated in FIG. 6, an 8-bit adder is considered (in other words the adder 16 is configured to add a number a encoded over eight bits with another number b encoded over eight bits, and to output the result in the form of a number c also encoded over eight bits), and the number L is equal to one (in other words, only the least significant bit c[7] of the result is affected by the predetermined region 21).

As illustrated in FIG. 6, the predetermined region 21 is connected to a voltage source 17 for applying a back-gate voltage to the FDSOI transistors 30 of the region 21. The value V_{BB} of the back-gate voltage may be dynamically controlled by the control circuit 15. The other transistors which implement the adder 16 and which are not part of the predetermined region 21 are subjected to a reference voltage VREF.

As illustrated in FIG. 3, the control circuit 15 is configured to control the back-gate voltage value applied to the predetermined region 21. More particularly, the control circuit 15 is configured to apply by default the back-gate voltage reference value VREF, and to apply a back-gate voltage specific value V_{BB}, different from the reference value (V_{REF}≠V_{BB}), only during the execution of the addition(s) that are to be performed in an approximate manner.

The transistor type (“Regular Well”, “Flip Well”) and the back-gate voltage specific value V_{BB} may be selected such that the threshold voltage of the FDSOI transistors 30 of the predetermined region 21 is higher with a back-gate voltage equal to V_{BB} than with a back-gate voltage equal to VREF. With such arrangements, applying the back-gate voltage specific value V_{BB} results in a degradation of the performances of the FDSOI transistors 30 of the predetermined region 21. Thus, for the clock cycles where the back-gate voltage specific value V_{BB} is applied, the adder 16 behaves like an approximate adder. However, for the clock cycles where the back-gate voltage reference value VREF is applied, the adder 16 behaves like an exact adder. For example, it is possible to consider that VREF is at OV.

There are two ways for applying a polarisation to the substrate 36: the so-called “forward polarisation” mode (FBB, for “Forward Body Bias”) and the so-called “reverse polarisation” mode (RBB, for “Reverse Body Bias”).

In general, for an NMOS transistor, if V_{BB} is positive, it corresponds to a “forward polarisation” (FBB), and therefore to an improvement in the performances of the transistor. However, if V_{BB} is negative, it corresponds to a “reverse polarisation” (RBB), and therefore to a degradation in the performances of the transistor.

For a PMOS-type transistor, the reverse applies: if V_{BB} is positive, it corresponds to a “reverse polarisation” (RBB), and if V_{BB} is negative, it corresponds to a “forward polarisation” (FBB).

A CMOS structure includes both an NMOS transistor and a PMOS transistor. A CMOS structure according to the FDSOI technology may be optimised for either one of the FBB and RBB modes.

In the present invention, the FDSOI transistors 30 are advantageously arranged into CMOS structures optimised for the RBB mode.

FIG. 5 schematically shows an FDSOI CMOS structure optimised for the RBB mode. The CMOS structure includes an FDSOI transistor 30a of the NMOS type on a P-well and a FDSOI transistor 30b of the PMOS type on a N-well. Thus, in the CMOS structure illustrated in FIG. 5, the substrate 36a of the NMOS transistor 30a is of the P type ( ). However, the source 31a and the drain 32a are of the N type. The substrate 36b of the PMOS transistor 30b is of the N type. However, the source 31b and the drain 32b are of the P type. This corresponds to a so-called “conventional” circuit (“Regular Well”) optimised for the RBB mode, i.e. allowing favouring high threshold voltages (RVT or HVT).

Nonetheless, it should be noted that nothing would prevent from using CMOS structures with an NMOS on an N-well and a PMOS on a P-well (a circuit so-called “Flip Well”). Nonetheless, such a circuit is generally optimised for the FBB mode, i.e. to favour low threshold voltages (LVT).

The second embodiment described with reference to FIG. 3 corresponds to a particularly compact architecture (since it includes one single adder). Furthermore, this second embodiment allows for an enhanced level of flexibility on the error distribution that can be obtained. Indeed, it is possible to configure the control circuit 15 to dynamically determine the back-gate voltage value to be applied according to an error probability level desired for the computation of the scalar product. The back-gate voltage allows varying the threshold voltage of the FDSOI transistors 30 of the region 21. A higher threshold voltage results in an increase in the propagation time of the logic gates implemented by these transistors, and consequently a loss of accuracy in the computations.

The graph shown in FIG. 7 illustrates the possibility of controlling the error probability level as a function of the back-gate voltage V_{BB} applied by the dynamic voltage source 17. This graph shows the error probability level (a value comprised between 0 and 1), as a function of the back-gate voltage V_{BB} (in Volt), in the case where one single least significant bit of the result of the addition is affected. One could observe in this graph that the error probability level increases with the back-gate voltage and tends towards a limit value of 0.5. The measurements shown in the graph of FIG. 7 have been obtained on a digital circuit 10 similar to that one described before with reference to FIG. 3.

The selection of the number L of least significant bits that one wishes to have affected by the approximate computation, and therefore indirectly the determination of the region 21, also contribute to the definition of the error distribution. Nonetheless, this aspect is static since it is defined upon design of the digital circuit 10, and can no longer by changed later on.

What has been mentioned before for the first embodiment with regards to the possibility of configuring the control circuit 15 to dynamically control which additions should be performed in an approximate manner in the computation of the scalar product also applies to the second embodiment.

The description hereinbefore clearly illustrates that, by its different features and their advantages, the present invention achieves the set objectives. In particular, the digital circuit 10 according to the invention allows implementing a cryptographic primitive for an LWE-type algorithm, without having to use any TRNG or PRNG type hardware component, and while keeping a particularly simple, compact and energy-efficient architecture.

The proposed solution also allows for a good flexibility and a good accuracy on the error probability that can be obtained for the computation of the scalar product, as well as the possibility of introducing entropy into the obtained error distribution.

In particular, the invention has been described for a post-quantum cryptography application. However, nothing excludes considering using the digital circuit 10 according to the invention for other applications, in particular in order to reduce the energy consumption of the system. For example, the digital circuit 10 may be used in other applications requiring vector computation accelerators, to the extent that these applications are resilient to a determined degree of approximation (for example to implement neural networks, in particular in the context of image processing). The digital circuit 10 according to the invention then allows for a good flexibility in the implementation of a trade-off between computation accuracy and energy consumption.

1. A digital circuit for computing a scalar product between two N-dimension vectors, N being an integer at least equal to two, the two vectors being respectively denoted (a₀, a₁, . . . , aⱼ, . . . , a_{N-1}) and (s₀, s₁, . . . , sⱼ, . . . , s_{N-1});
the digital circuit including a multiplier, an accumulator including at least one adder and a register, as well as a control circuit of the accumulator;
the digital circuit is configured to be clocked by a clock, and at a clock tick of index j, j being an integer varying between 0 and (N−1):
the multiplier is configured to compute a result rⱼ of a multiplication aⱼ×sⱼ of the components of index j of the two vectors,
the accumulator is configured to add the result rⱼ of the multiplication with a current value of the register, and to memorise a result of the addition in the register;
the control circuit is configured to control the accumulator so as to perform the addition in an approximate manner, i.e. with a predetermined level of probability that the result of the addition includes an error, for at least one addition amongst the N additions of the computation of the scalar product.

2. The digital circuit according to claim 1, wherein:
the accumulator includes one single adder implemented according to the “Fully-Depleted Silicon-On-Insulator”, FDSOI, technology;
a predetermined region of the adder groups together FDSOI transistors forming logic gates which control a predetermined number L of least significant bits of the result of the addition, L being an integer at least equal to one;
said predetermined region is connected to a voltage source for applying a back-gate voltage to the FDSOI transistors of the region, the value of the back-gate voltage being dynamically controllable by the control circuit,
the control circuit is configured to apply by default a back-gate voltage reference value, and to apply a back-gate voltage specific value, different from the reference value, only during the execution of said at least one addition to be performed in an approximate manner.

3. The digital circuit according to claim 2, wherein the control circuit is configured to dynamically determine the back-gate voltage specific value to be applied according to an error probability level desired for the computation of the scalar product.

4. The digital circuit according to claim 1, wherein the FDSOI transistors are arranged into CMOS structures each including an NMOS transistor on a P well and a PMOS transistor on an N well.

5. The digital circuit according to claim 1, wherein:
the accumulator includes an exact adder synthesised specifically to compute an addition in an exact manner, an approximate adder synthesised specifically to compute an addition with the predetermined error probability level, and a multiplexer;
for each addition executed at a clock tick of index j, the multiplexer is configured by the control circuit to select the adder to be used amongst the exact adder and the approximate adder.

6. The digital circuit according to claim 1, wherein said at least one addition to be executed in an approximate manner, amongst the N additions of the computation of the scalar product, is different at each new scalar product computation.

7. The digital circuit according to claim 1, wherein said at least one addition to be executed in an approximate manner in the computation of the scalar product is randomly selected.

8. The digital circuit according to claim 1, wherein the number of additions to be executed in an approximate manner in the computation of the scalar product is dynamically controlled by the control circuit according to an error probability level desired for the computation of the scalar product.

9. An electronic device implementing a cryptographic algorithm based on a “Learning With Errors”, LWE, technology, said device comprising at least one digital circuit according to claim 1.
